(19) United States
(12) Patent Application Publication
(10) Pub. No.: US 2006/0186451 A1
(43) Pub. Date: Aug. 24, 2006

(54) Memory device for storing electric charge, and method for fabricating it

(76) Inventors: Georg Dusberg, Dresden, DE (US); Andrew Graham, Munchen (DE); Franz Kreupl, Munchen (DE)

Correspondence Address: JENKINS, WILSON, TAYLOR & HUNT, P. A., 3100 TOWER BLVD, SUITE 1200, DURHAM, NC, 27707, US

(21) Appl. No.: 11/363,991

(22) Filed: Feb. 28, 2006

Related U.S. Application Data
(63) Continuation of application No. PCT/EP04/10085, filed on Sep. 9, 2004.

(30) Foreign Application Priority Data
Sep. 26, 2003 (DE) 10344814.4

(51) Int. Cl. H01L 29/94; H01L 21/8242

(52) U.S. Cl. 257/306; 257/E27.094; 438/244

(57) ABSTRACT

The present device relates to memory devices for storing electric charge having memory cells and transistors arranged spatially next to them, and relates in particular to memory devices having memory cells with a high capacitance. In the memory cells which form a memory device to which the invention relates, there is a substrate and at least one memory cell which is arranged on the substrate and includes a first electrode element, which is electrically connected to the substrate, an insulation layer, which has been applied to the first electrode element, and a second electrode element, which has been applied to the insulation layer and is electrically insulated from the first electrode element.

### RELATED APPLICATIONS

This application is a continuation of PCT patent application number PCT/EP2004/010085, filed Sep. 9, 2004, which claims priority to German patent application number 10344814.4, filed Sep. 26, 2003, the disclosures of each of which are incorporated herein by reference in their entirety.

The present invention relates in general terms to memory devices for storing electric charge having memory cells and transistors arranged spatially next to them, and relates in particular to memory devices having memory cells with a high capacitance.

In the memory cells which form a memory device to which the invention relates, there is a substrate and at least one memory cell which is arranged on the substrate and includes a first electrode element, which is electrically connected to the substrate, an insulation layer, which has been applied to the first electrode element, and a second electrode element, which has been applied to the insulation layer and is electrically insulated from the first electrode element.

Conventional memory devices comprise a trench capacitor, which is coupled to a horizontally or vertically oriented transistor based on silicon or crystalline silicon, with the transistor being arranged spatially next to the capacitor. To provide the capacitors with a storage capacity, a certain minimum capacitance is required in order to generate a measurable signal which is greater than the thermal noise. This minimum capacitance is typically 30 fF (femtofarad, 10⁻¹² farad).

Ongoing miniaturization requires the provision of ever smaller structures for the storage capacitor. This scaling of the capacitors entails considerable problems, which include the difficulty of a continuous, uniform coating of the capacitor with a dielectric, the production of small electrodes with sufficient mechanical stability while maintaining the capacitance, etc.

One significant drawback of conventional memory devices consists in the fact that a capacitance is insufficient, since it is not possible to provide a sufficiently large electrode surface area and/or a sufficiently thin dielectric.

Proceeding from this prior art, the invention is based on the object of providing a memory device and a method for fabricating a memory device, memory cells that are present in the memory device having a sufficient storage capacity.

According to the invention, this object is achieved by a memory device for storing electric charge having the features of claim 1.

Furthermore, the object is achieved by a method as described in patent claim 9.

Further configurations of the invention will emerge from the subclaims.

One important concept of the invention consists in providing one of the electrode elements which form the capacitor of a memory cell with a high aspect ratio, i.e. a great length compared to the dimensions of a base area, so that an increase in the capacitance of the memory cells associated with an increase in the surface area of the electrode is provided. According to the invention, a nanotube (NT) having a high aspect ratio and a sufficient mechanical stability is provided as a first electrode element, which is electrically connected to the substrate.

One significant benefit of the method according to the invention comprises providing a nanotube as a first electrode element consists in the fact that it is possible to use standardized lithography processes while structures with sub-lithographic features can be produced.

It is thus advantageously possible to increase a capacitance of the memory cell by virtue of the fact that it is possible to provide a nanotube of small diameter which is below a feature size of the standardized lithography.

The memory device for storing electric charge is advantageously produced by means of standardized processes of chemical vapor deposition (CVD) and/or atomic layer deposition (ALD).

The memory device according to the invention for storing electric charge substantially includes:

a) a substrate;

b) at least one memory cell which is arranged on the substrate and includes a first electrode element, which is electrically connected to the substrate, an insulation layer, which has been applied to the first electrode element, and a second electrode element, which has been applied to the insulation layer and is electrically insulated from the first electrode element, the first electrode element, which is electrically connected to the substrate, being provided as a nanotube with a high aspect ratio.

Furthermore, the method according to the invention for fabricating a memory device for storing electric charge substantially includes the following steps:

a) providing a substrate; and

b) providing at least one memory cell arranged on the substrate by a first electrode element, which is electrically connected to the substrate, being grown on the substrate, an insulation layer being applied to the first electrode element, and a second electrode element, which is electrically insulated from the first electrode element, being applied to the insulation layer, in which method the first electrode element, which is electrically connected to the substrate, is grown on the substrate as a nanotube with a high aspect ratio.

According to a preferred refinement of the present invention, the first electrode element, which is electrically connected to the substrate, is formed as a carbon nanotube (CNT).

According to a further preferred refinement of the present invention, the insulation layer is provided as a dielectric with a dielectric constant (k) in the range from 10 to 25.

According to yet another preferred refinement of the present invention, the second electrode element, which has been applied to the insulation layer and is electrically insulated from the first electrode element, is formed as a metallization layer. By way of example, the metallization layer is provided from a polysilicon material.

According to yet another preferred refinement of the present invention, between the substrate and the first electrode element is arranged an interlayer system, which includes a barrier layer, which has been applied to the substrate, and a catalyst layer, which has been applied to the barrier layer and on which the first electrode element can be grown. It is preferable for the catalyst layer to contain at least one element from an iron group (Fe, Ni, Co), in such a manner that the first electrode element grows in the form of a carbon nanotube (CNT). In a further aspect of the present invention, the catalyst layer contains a silicide-forming material, such as for example Au, Pt, Ti, in such a manner that a silicon nanowire or a form of nanowire that is different grows and serves as the first electrode element.

According to a further aspect of the present invention, the insulation layer, which is applied to the first electrode element, is produced by means of chemical vapor deposition. In another preferred refinement of the present invention, the insulation layer, which is applied to the first electrode element, is produced by means of atomic layer deposition (ALD).

According to yet another preferred refinement of the present invention, the first electrode element, which is electrically connected to the substrate, is grown on the substrate by means of chemical vapor deposition (CVD).

By way of example, the substrate is provided from a silicon material. It is advantageous if the second electrode element, which is electrically insulated from the first electrode element and is applied to the insulation layer, is provided from a polysilicon or other metallic material.

Exemplary embodiments of the invention are illustrated in the drawings and explained in more detail in the description below.

In the drawings:

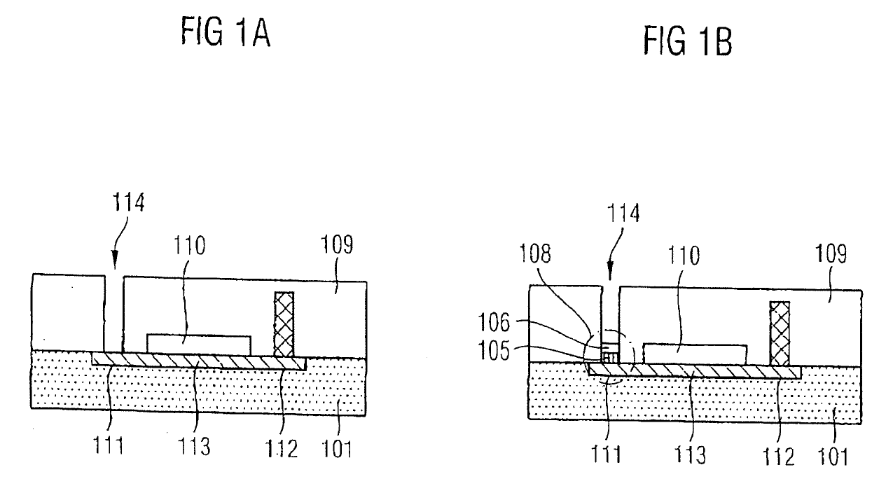

FIG. 1 shows the first two process steps a) and b) used to fabricate a memory device in accordance with a preferred exemplary embodiment of the present invention; and

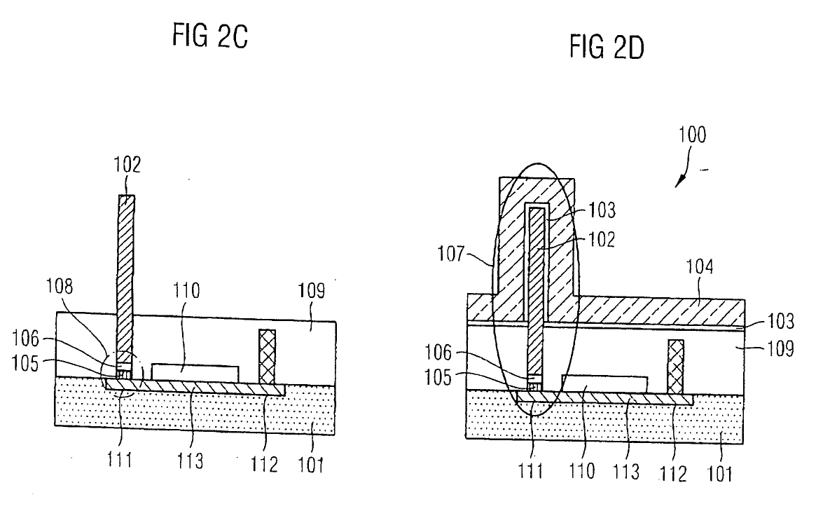

FIG. 2 shows two further process steps c) and d), which follow the process steps shown in FIG. 1, for fabricating a memory device for storing electric charge in accordance with the preferred exemplary embodiment of the present invention.

In the figures, identical reference numerals denote identical or functionally equivalent components or steps.

In process step a) shown in FIG. 1, a substrate 101, which is provided with an oxide layer 109, for example of an SiO₂ material, is provided. In the arrangement shown in FIG. 1(a), a transistor, which is provided next to a memory cell and comprises a gate element 110, a drain element 111 and a source element 112 as well as a channel 113, has already been applied.

It should be noted that the transistor illustrated is only an example and can be designed in various ways. According to the invention, in process step a) a cutout 114, in which the memory cell is formed in the further process steps c) to d), is etched into the oxide layer 109. The trench structure 114 is etched into the oxide layer 109, for example by an anisotropic etch.

In process step b), which follows process step a), first of all a barrier layer 105 is deposited in the cutout 114. A barrier layer 105 of this type serves as contact material to the substrate 101 below, which is preferably formed from silicon. It should be noted that the barrier layer, which acts as a diffusion barrier, can be deposited before or after deposition of the oxide layer 109. After deposition of the barrier layer 105, a catalyst layer 106, which serves as a catalyst for the growth of nanotubes according to the invention in order to increase a capacitance of the memory cell element, is applied. Like the barrier layer 105, the catalyst layer 106 is selected in such a manner as to provide sufficient electrical contact to the silicon substrate 101.

FIG. 2, in process steps c) and d), shows the completion of the capacitor, which serves as a memory cell of a memory cell array. It should be noted that the process steps a) to d) shown in FIGS. 1 and 2 are only examples, i.e. it is possible in particular for a large number of memory cells to be deposited in parallel.

Process step c) shown in FIG. 2 shows how a nanotube, typically a multi-walled carbon nanotube (CNT), or some other form of mechanically stable, conducting wire, such as for example a silicon nanowire, is grown on the catalyst material. To produce carbon nanotubes (CNTs), it is advantageous if the catalyst layer 106 is formed from at least one element from an iron group, such as for example Fe, Ni or Co.

Furthermore, it is possible for the catalyst layer 106 to contain a silicide-forming material, such as for example Au, Pt or Ti, in such a manner that the first electrode element 102 grows as a silicon nanowire on the catalyst layer 106. According to the invention, the first electrode element, which is formed as a nanotube (NT), projects out of the surface of the oxide layer 109.

It is advantageously possible, by means of the growth process of the nanotubes, to produce very thin electrode elements of considerable length. The length of carbon nanotubes is typically 0.5 mm, while their diameter is 10 nm. It should be noted that the feature size of the diameter of the nanotubes is below the resolution of the standardized lithography processes which are used to produce the memory cells and/or the associated transistors with their gate elements, drain elements and source elements.

This means that by means of the patterning with carbon nanotubes and/or silicon nanowires, it is possible to introduce sub-lithographic features using standardized lithography processes. On account of the high mechanical stability of the first electrode element, which is designed as a nanotube, it is possible for this element to project up to 0.5 mm out of the surface of the oxide layer 109.

Process step d) shown in FIG. 2 is used to complete the capacitor element forming a memory cell. An insulation layer 103 is deposited as a dielectric on the entire structure which has been obtained thus far, i.e. the first electrode element 102 and the oxide layer 109, it is preferable for the insulation layer to be deposited by means of chemical vapor deposition, a standardized process which is well known to an average person skilled in the art.

Furthermore, it is advantageous to use atomic layer deposition (ALD) in order to obtain particularly thin dielectric layers. Since the capacitance of the memory cell obtained and the thickness of the dielectric layer are inversely proportional to one another, the capacitance is in this way increased.

In particular, the method according to the invention also provides an increase in the capacitance by increasing the electrode surface area, since the first electrode element 102 now projects out of the surface of the oxide layer 109. A second electrode element 104 is applied as counterelectrode to the structure obtained, i.e. substantially to the deposited insulation layer 103. The second electrode element 104 is preferably formed as a metallization layer. By way of example, polysilicon is used as material for the second electrode element 104.

It should be noted that an interlayer system 108 which is arranged between the substrate 101 and the first electrode element 102 and which comprises a barrier layer 105 applied to the substrate and a catalyst layer 106 deposited on the barrier layer 105 can be replaced by other layer systems.

One important feature of the interlayer system 108 is that it provides sufficient electrical contact between the first electrode element and the silicon substrate as a base electrode. The circled region denoted by reference numeral 107 in FIG. 2(d) therefore represents a memory cell which comprises a capacitor with electrodes of increased surface area, i.e. a first electrode element 102 and a second electrode element 104 with a dielectric located between them in the form of the insulation layer 103.

Therefore, one major benefit of the method according to the invention is that it is possible to produce memory devices with memory cells in which the central electrode can be provided so as to project out of a surface of the oxide layer 109 with a length of several tenths of a micrometer and a uniform diameter. In particular, it is advantageous that the carbon nanotubes used and/or the silicon nanowires have a high electrical conductivity. A further advantage is that the nanotubes formed as the first electrode element 102 are matched to the hole diameter which has been etched into the oxide layer 109 in process step a). Unlike in conventional methods, the method according to the invention allows three-dimensional patterning using standardized 2D coating processes. Whereas there are limits on the extent to which a capacitance of a memory cell can be increased by increasing the dielectric constant of the insulation layer 103 functioning as a dielectric, i.e. the dielectric constant is limited to typically between 10 and 25, it is possible to increase the capacitance by growing the first electrode element 102 out of the plane of the oxide layer 109 as a result of the increase in surface area, whereas the lateral dimensions of the memory device are not increased.

Although the present invention has been described above on the basis of preferred exemplary embodiments, it is not restricted to these embodiments, but rather can be modified in numerous ways.

Also, the invention is not restricted to the possible applications mentioned.

### LIST OF DESIGNATIONS

In the figures, identical reference numerals denote identical or functionally equivalent components or steps.
100 Memory device
101 Substrate
102 First electrode element
103 Insulation layer
104 Second electrode element
105 Barrier layer
106 Catalyst layer
107 Memory cell
108 Interlayer system
109 Oxide layer
110 Gate element
111 Drain element
112 Source element
113 Channel
114 Trench structure

1. A memory device (100) for storing electric charge, having:
a) a substrate (101); and
b) at least one memory cell (107) which is arranged on the substrate (101) and includes:
b1) a first electrode element (102), which is electrically connected to the substrate (100);
b2) an insulation layer (103), which has been applied to the first electrode element (102); and
b3) a second electrode element (104), which has been applied to the insulation layer (103) and is electrically insulated from the first electrode element (102),
in which memory device
the first electrode element (102), which is electrically connected to the substrate (101), is provided as a nanotube (NT) with a high aspect ratio;
characterized in that
between the substrate (101) and the first electrode element (102) is arranged an interlayer system (108), which includes:
a) a barrier layer (105), which has been applied to the substrate (101); and
b) a catalyst layer (106), which has been applied to the barrier layer (105) and on which the first electrode element (102) can be grown, and
the catalyst layer (106) containing a silicide-forming material (Au, Pt, Ti), in such a manner that the first electrode element (102) grows as a silicon nanowire.

2. The device as claimed in claim 1,
characterized in that
the insulation layer (103) is provided as a dielectric with a dielectric constant in the range from 4 to 600.

3. The device as claimed in claim 1,
characterized in that
the second electrode element (104), which has been applied to the insulation layer (103) and is electrically insulated from the first electrode element (102), is formed as a metallization layer.

4. A memory cell array having a multiplicity of memory devices as claimed in one or more of claims 1 to 7 arranged next to one another.

5. A method for fabricating a memory device (100) for storing electric charge, comprising the following steps:
a) providing a substrate (101); and
b) providing at least one memory cell (107) arranged on the substrate (101), by
b1) a first electrode element (102), which is electrically connected to the substrate (101), being grown on the substrate (101);
b2) an insulation layer (103) being applied to the first electrode element (102); and
b3) a second electrode element (104), which is electrically insulated from the first electrode element (102), being applied to the insulation layer (103),
in which method the first electrode element (102), which is electrically connected to the substrate (101), is grown on the substrate (101) as a nanotube (NT) with a high aspect ratio;
characterized in that
an interlayer system (108) is arranged between the substrate (101) and the first electrode element (102), and wherein
a) a barrier layer (105) is applied to the substrate (101); and
b) a catalyst layer (106), on which the first electrode element (102) is grown, is applied to the barrier layer (105), and the catalyst layer (106) is formed by a silicide-forming material (Au, Pt, Ti), in such a manner that the first electrode element (102) grows as a silicon nanowire.

6. The method as claimed in claim 5,
characterized in that
the insulation layer (103) is provided as a dielectric with a dielectric constant in the range from 4 to 600.

7. The method as claimed in claim 5,
characterized in that
the second electrode element (104), which is applied to the insulation layer (103) and is electrically insulated from the first electrode element (102), is applied as a metallization layer.

8. The method as claimed in claim 5,
characterized in that
the insulation layer (103), which is applied to the first electrode element (102), is produced by means of chemical vapor deposition (CVD).

9. The method as claimed in claim 5,
characterized in that
the insulation layer (103), which is applied to the first electrode element (102), is produced by means of atomic layer deposition (ALD).

10. The method as claimed in claim 5,
characterized in that
the first electrode element (102), which is electrically connected to the substrate (101), is grown on the substrate (101) by means of chemical vapor deposition (CVD).

11. The method as claimed in claim 5,
characterized in that
the substrate (101) is provided from a silicon material.

12. The method as claimed in claim 5,
characterized in that
the second electrode element (104), which is electrically insulated from the first electrode element (102) and is applied to the insulation layer (103), is provided from a conducting, for example metallic, material.
